(19) United States
(12) Patent Application Publication
(10) Pub. No.: US 2017/0320294 A1
(43) Pub. Date: Nov. 9, 2017

(54) GLASS LAMINATE AND PORTABLE ELECTRONIC DEVICE

(71) Applicant: ASAHI GLASS COMPANY, LIMITED, Chiyoda-ku (JP)

(72) Inventors: Hiroyuki YAMAMOTO, Haibara-gun (JP); Takahiro SAKAGAMI, Haibara-gun (JP); Tomoharu HASEGAWA, Chiyoda-ku (JP); Chika YASUI, Haibara-gun (JP)

(73) Assignee: ASAHI GLASS COMPANY, LIMITED, Chiyoda-ku (JP)

(21) Appl. No.: 15/661,553

(22) Filed: Jul. 27, 2017

Related U.S. Application Data
(63) Continuation of application No. PCT/JP2016/052736, filed on Jan. 29, 2016.

(30) Foreign Application Priority Data
Jan. 30, 2015 (JP) 2015-016844

(51) Int. Cl. B32B 17/06; B32B 7/02; C03C 17/34; H05K 5/02; H05K 5/00

(52) U.S. Cl. CPC B32B 17/06; B32B 7/02; C03C 17/3417; C03C 2218/154; C03C 2217/734; C03C 2217/218; B32B 2457/00; B32B 2307/538; B32B 2307/418; H05K 5/0086; H05K 5/02; C03C 2217/213

(57) ABSTRACT

A glass laminate includes a glass substrate; and an anti-reflection layer laminated on the glass substrate and a minimum of absorbances of the glass laminate in wavelengths of 380 to 780 nm is 0.01 or more.

### CROSS-REFERENCE TO RELATED APPLICATIONS

This application is a continuation of prior International Application No. PCT/JP2016/052736, filed on Jan. 29, 2016 which is based upon and claims the benefit of priority from Japanese Patent Application No. 2015-016844, filed on Jan. 30, 2015; the entire contents of all of which are incorporated herein by reference.

### FIELD

The present invention relates to a glass laminate and a portable electronic device, and in particular relates to a glass laminate excellent in design and a portable electronic device using this.

### BACKGROUND

Regarding a casing of an electronic device such as a mobile phone, or the like, an appropriate material is selected from materials such as resin and metal in consideration of various factors such as decorativeness, scratch resistance, workability, and cost.

In recent years, as a material constituting a casing of an electronic device, or the like, there have been attempts to use glass that has not been used hitherto. Using the glass for the material constituting the casing of the electronic device, or the like makes it possible to obtain a unique decorative effect with transparency (for example, refer to Patent Reference 1: JP-A 2009-061730).

On the other hand, when the glass is used for the material constituting the casing of the electronic device, or the like, a light blocking property is not necessarily sufficient. For example, when a light source or the like is provided inside, this inside light source or the like is easily recognized from the outside. Therefore, for a material constituting a casing of an electronic device, or the like, there have been attempts to use glass having a predetermined absorption constant (for example, refer to Patent Reference 2: WO 2012/124758 A1)

### SUMMARY

Conventionally, there have been attempts to use glass for a material constituting a casing of an electronic device, or the like. Using the glass for the material constituting the casing of the electronic device, or the like makes it possible to obtain a decorative effect unique to glass. However, the glass to be used for such an exterior use is required to make design even better.

The present invention has been made in order to solve the above-described problems, and an object thereof is to provide a glass laminate which is suitably used for an exterior use such as a casing of an electronic device and is excellent in design.

A glass laminate of the present invention includes: a glass substrate; and an anti-reflection layer laminated on the glass substrate. Further, in the glass laminate of the present invention, a minimum of the absorbances in the wavelengths of 380 to 780 nm is 0.01 or more.

According to the present invention, it is possible to provide a glass laminate which is suitably used for a casing of an electronic device, or the like and is excellent in design. In particular, according to the present invention, it is possible to provide a glass laminate having depth in color.

### BRIEF DESCRIPTION OF THE DRAWINGS

FIG. 1 is a sectional view illustrating one embodiment of a glass laminate.

FIG. 2 is a sectional view illustrating an anti-reflection layer of the glass laminate illustrated in FIG. 1.

FIG. 3 is a chart illustrating a measurement result of spectral reflectance in Example 21.

FIG. 4 is a chart illustrating a measurement result of spectral reflectance in Example 22.

FIG. 5 is a chart illustrating a measurement result of spectral reflectance in Example 23.

FIG. 6 is a chart illustrating a measurement result of spectral reflectance in Example 24.

FIG. 7 is a chart illustrating a measurement result of spectral reflectance in Example 25.

FIG. 8 is a chart illustrating a measurement result of spectral reflectance in Example 26.

FIG. 9 is a chart illustrating a measurement result of spectral reflectance in Example 27.

FIG. 10 is a chart illustrating a measurement result of spectral reflectance in Example 28.

### DETAILED DESCRIPTION

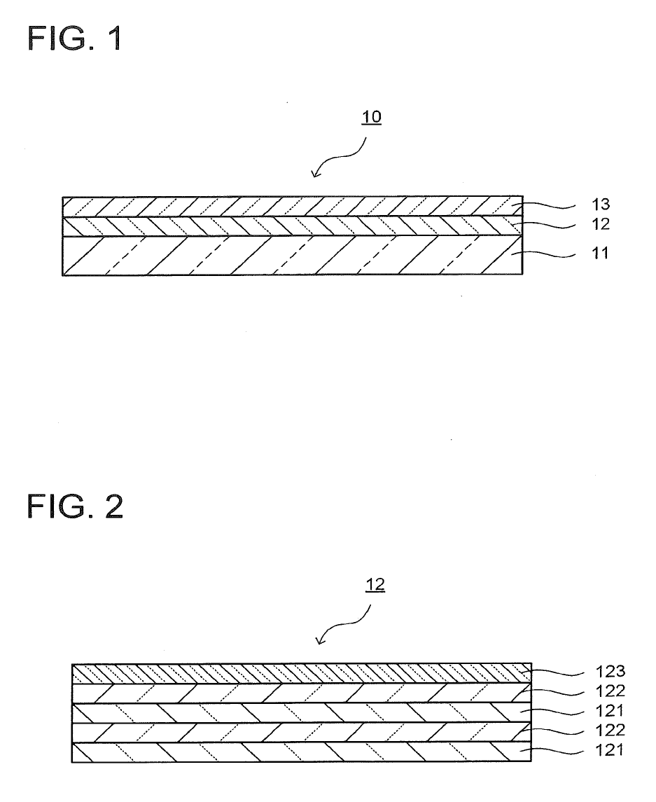

Hereinafter, a mode for carrying out the present invention will be described. FIG. 1 is a sectional view illustrating one embodiment of a glass laminate. Further, FIG. 2 is a sectional view illustrating an anti-reflection layer of the glass laminate illustrated in FIG. 1.

A glass laminate 10 has a glass substrate 11, an anti-reflection layer 12, and an antifouling layer 13, for example. The anti-reflection layer 12 and the antifouling layer 13 are provided on one principal surface side of the glass substrate 11 in this order.

In the glass laminate 10, a minimum of the absorbances in the wavelengths of 380 to 780 nm is 0.01 or more. When the above-described minimum is 0.01 or more, an external appearance of the glass laminate 10 becomes colored. When the external appearance of the glass laminate 10 becomes colored as described above, depth is given its color and design is improved by providing the anti-reflection layer 12. In particular, in such a case that the color of the glass laminate 10 is a black color or a deep color, the depth is given the black color or the deep color and the design is improved by providing the anti-reflection layer 12. For example, when the color of the glass laminate 10 is the black color or the deep color, gloss and something likely to be whiteness on a surface are suppressed and a color having the depth can be obtained.

Hereinafter, each composing member of the glass laminate 10 will be described.

The glass substrate 11 is made of a glass material and the minimum of the absorbances of the glass laminate 10 in the wavelengths of 380 to 780 nm is 0.01 or more. From the viewpoint of setting the minimum of the absorbance of the glass laminate 10 in the wavelengths of 380 to 780 nm to 0.01 or more, a minimum of the absorbances of the glass substrate 11 in the wavelengths of 380 to 780 nm is preferably 0.01 or more. As the glass substrate 11 as described above, colored glass is preferable.

As the colored glass, the one containing a coloring component in glass is preferable. As the coloring component, there can be cited metal oxides of Co, Mn, Fe, Ni, Cu, Cr, V, Bi, Se, Ti, Ce, Er, Nd, and so on. Specifically, there can be cited Co₃O₄, MnO, MnO₂, Fe₂O₃, NiO, CuO, Cu₂O, Cr₂O₃, V₂O₅, Bi₂O₃, SeO₂, TiO₂, CeO₂, Er₂O₃, Nd₂O₃, and so on. As the coloring component, only one type may be used or two or more types may be used.

A content of the coloring component is preferably 0.001 to 7% in terms of molar percentage on an oxide basis in the colored glass. When the content of the coloring component is less than 0.001%, an effect as the coloring component cannot be sufficiently obtained. Thereby, the minimum of the absorbances of the glass substrate 11 in the wavelengths of 380 to 780 nm does not become 0.01 or more, and as a result there is a possibility that the minimum of the absorbances of the glass laminate 10 in the wavelengths of 380 to 780 nm does not become 0.01 or more.

The content of the coloring component is preferably 0.1% or more, more preferably 0.2% or more, further preferably 1% or more, and particularly preferably 2% or more from the viewpoint of obtaining the color having the depth. Further, when the content of the coloring component exceeds 7%, there is a possibility that glass becomes unstable to cause devitrification. The content of the coloring component is preferably 5% or less, and more preferably 4% or less from the viewpoint of stability of the glass, and the like.

The colored glass preferably contains 55 to 80% SiO₂, 0 to 16% Al₂O₃, 0 to 12% B₂O₃, 5 to 20% Na₂O, 0 to 8% K₂O, 0 to 15% MgO, 0 to 15% CaO, O to 18% ΣRO (R is Mg, Ca, Sr, Ba, and Zn), and 0 to 5% ZrO₂ in terms of molar percentage on an oxide basis together with the coloring component. Hereinafter, composition of the glass other than the coloring component in the colored glass will be described using a content in terms of molar percentage unless otherwise specified.

SiO₂ is a component which constitutes a skeletal structure of the glass, and is essential. When its content is less than 55%, there is a possibility that stability and weather resistance of the glass decrease. Its content is preferably 60% or more, and more preferably 65% or more. When its content is more than 80%, there is a possibility that viscosity of the glass increases and meltability decreases. Its content is preferably 75% or less, and more preferably 70% or less.

Al₂O₃ is a component which improves the weather resistance and a chemical tempering characteristic of the glass, and is not essential but can be contained as necessary. When its content becomes 1% or more, the weather resistance becomes good, which is therefore preferable. Its content is more preferably 2% or more, and further preferably 3% or more. When its content is more than 16%, there is a possibility that the viscosity of the glass becomes high and uniform melting becomes difficult. Its content is preferably 14% or less, and more preferably 12% or less.

B₂O₃ is a component which improves the weather resistance of the glass, and is not essential but can be contained as necessary. When its content becomes 4% or more, the weather resistance improves significantly, which is therefore preferable. Its content is more preferably 5% or more, and further preferably 6% or more. When its content is more than 12%, there is a possibility that striae due to volatilization occur and a yield decreases. Its content is preferably 11% or less, and further preferably 10% or less.

Na₂O is a component which improves the meltability of the glass, and further is contained in order to cause a surface compressive stress layer to be formed by ion exchange. When its content is less than 5%, there is a possibility that the meltability is poor and further it becomes difficult to form a desired surface compressive stress layer by ion exchange. Its content is preferably 7% or more, and more preferably 8% or more. When its content is more than 20%, there is a possibility that the weather resistance decreases. Its content is preferably 18% or less, and more preferably 17% or less.

K₂O is not essential but a component which improves the meltability of the glass, and, in addition, has an operation which increases an ion exchange speed in chemical tempering, and therefore it is preferably contained. When its content becomes 0.01% or more, the meltability, the ion exchange speed, and the like improve significantly, which is therefore preferable. Its content is more preferably 0.1% or more. When its content is more than 8%, there is a possibility that the weather resistance decreases. Its content is preferably 6% or less, and more preferably 5% or less.

MgO is a component which improves the meltability of the glass, and is not essential but can be contained as necessary. When its content becomes 3% or more, the meltability improves significantly, which is therefore preferable. Its content is more preferably 4% or more. When its content is more than 15%, there is a possibility that the weather resistance decreases. Its content is preferably 13% or less, and more preferably 12% or less.

CaO is a component which improves the meltability of the glass, and can be contained as necessary. When its content becomes 0.01% or more, the meltability improves significantly, which is therefore preferable. Its content is more preferably 0.1% or more. When its content is more than 15%, there is a possibility that the chemical tempering characteristic decreases. Its content is preferably 13% or less, and more preferably 12% or less.

One or more types to be selected from SrO, BaO, and ZnO can also be contained as necessary other than MgO and CaO. SrO, BaO, and ZnO are also a component which improves the meltability of the glass. When a total content (ΣRO) of these ROs (R represents Mg, Ca, Sr, Ba, and Zn) becomes 1% or more, the meltability improves, which is therefore preferable. It is more preferably 3% or more, and further preferably 5% or more. When it is more than 18%, the weather resistance decreases. It is preferably 15% or less, more preferably 13% or less, and further preferably 11% or less.

ZrO₂ is a component which increases the ion exchange speed, and is not essential but can be contained in a range of 5% or less. When its content is more than 5%, there is a possibility that the meltability worsens and it remains as an unmelted substance in the glass.

Various forming methods can be adopted for formation of the colored glass. Specifically, there can be cited a down-draw method, a float method, a roll-out method, a pressing method, or the like. As the down-draw method, there can be cited an overflow down-draw method, a slot down method, a redraw method, or the like.

The colored glass may be chemically tempered by ion exchange treatment and provided with high strength. Chemical tempering increases strength by forming a compressive stress layer on a surface layer of the glass. Specifically, at a temperature below a glass transition point, alkali metal ions having a small ion radius are exchanged for alkali metal ions having a larger ion radius on the surface layer of the glass.

As the alkali metal ions having a small ion radius, Li ions, Na ions, or the like can be cited. For example, when the alkali metal ions having a small ion radius are the Li ions, Na ions, K ions, or the like can be cited as the alkali metal ions having a larger ion radius. Further, when the alkali metal ions having a small ion radius are the Na ions, the K ions or the like can be cited as the alkali metal ions having a larger ion radius.

The chemical tempering is performed by immersing the glass in heated sodium nitrate (NaNO₃) molten salt or potassium nitrate (KNO₃) molten salt, for example. Thereby, Li₂O on the surface layer of the glass is ion-exchanged for NaNO₃ in the molten salt, and further Na₂O on the surface layer of the glass is ion-exchanged for KNO₃ in the molten salt.

A condition of the chemical tempering can be appropriately selected depending on a thickness of the glass, but a condition indicated below is normally preferable. A treatment temperature of the chemical tempering is preferably 350 to 550° C., and more preferably 400 to 500° C. A treatment time of the chemical tempering is preferably 0.5 to 144 hours, and more preferably 1 to 24 hours.

In order to make an effect of strength improvement by the chemical tempering effective, it is preferable to make the surface compressive stress layer deeper than a microcrack which occurs on a surface of the glass. Here, the microcrack easily occurs when the surface of the glass is surface-roughened. From such a reason, a thickness of the surface compressive stress layer is preferably 6 μm or more.

Further, the glass easily breaks when a scratch which occurs at a time of use thereof exceeds the thickness of the surface compressive stress layer. Therefore, it is preferable to make the surface compressive stress layer thick. Specifically, it is more preferably 10 μm or more, further preferably 15 μm or more, further preferably 20 μm or more, and particularly preferably 30 μm or more.

On the other hand, when the surface compressive stress layer becomes too thick, internal tensile stress becomes large, and therefore impact at a time of breakage becomes large. That is, when the glass breaks, it becomes small pieces and easily scatters. In glass with a thickness of 2 mm or less, when a depth of a surface compressive stress layer exceeds 70 μm, scattering at a time of breakage becomes remarkable. Accordingly, the depth of the surface compressive stress layer is preferably 70 μm or less, more preferably 60 μm or less, further preferably 50 μm or less, and particularly preferably 40 μm or less.

Note that the depth of the surface compressive stress layer is found as follows.

For example, when a sodium component and a potassium component in molten salt are ion-exchanged in ion exchange treatment, the depth of the surface compressive stress layer can be found as follows. First, an alkali ion concentration analysis in a depth direction of the glass is performed by EPMA (electron probe micro analyzer). In this case, a potassium ion concentration analysis is performed. Then, a potassium ion diffusion depth obtained by measurement is regarded as the depth of the surface compressive stress layer.

Further, when a lithium component and a sodium component in molten salt are ion-exchanged in ion exchange treatment, the depth of the surface compressive stress layer can be found as follows. First, a sodium ion concentration analysis in the depth direction of the glass is performed by the EPMA. Then a sodium ion diffusion depth obtained by measurement is regarded as the depth of the surface compressive stress layer.

In the glass substrate 11, a surface roughness Ra measured in conformity with JIS B0633 (2001) is preferably 0.2 to 1 μm. When the surface roughness Ra becomes 0.2 μm or more, the strength improves, which is therefore preferable. Further, when the surface roughness Ra becomes 1 μm or less, a change in a visual aspect and a texture is suppressed to easily obtain a desired color. An adjustment of the surface roughness Ra can be performed by a physical method such as sandblasting or free abrasive polishing using an abrasive or a chemical method in which the glass substrate 11 is immersed in an etching solution. Measurement of the surface roughness Ra can be performed by a laser microscope (for example, manufactured by KEYENCE CORPORATION, model number: VK8550).

A thickness of the glass substrate 11 can be appropriately selected depending on a use or the like. From the viewpoint of securing the strength, it is preferably 0.1 mm or more, more preferably 0.2 mm or more, and further preferably 0.5 mm or more. Further, it is preferably 10 mm or less, more preferably 2.0 mm or less, and further preferably 1.2 mm or less.

The glass substrate 11 preferably has the following optical characteristics.

The minimum of the absorbance in the wavelengths of 380 to 780 nm is preferably 0.01 or more, more preferably 0.2 or more, further preferably 0.7 or more, and particularly preferably 1.0 or more. When the above-described minimum is 0.01 or more, the depth of the color of the glass laminate 10 increases, which is therefore preferable. The larger the above-described minimum becomes, the more the depth of the color of the glass laminate 10 increases, which is therefore preferable.

An average of the absorbance in the wavelengths of 380 to 780 nm is preferably 0.1 or more, more preferably 0.5 or more, further preferably 2.0 or more, and particularly preferably 3.0 or more. When the above-described average is 0.1 or more, the depth of the color of the glass laminate 10 increases in particular, which is therefore preferable. The larger the above-described average becomes, the more the depth of the color of the glass laminate 10 increases, which is therefore preferable.

A lightness L* of reflected light emitted from an F2 light source in an L*a*b* color system is preferably less than 40. When the lightness L* becomes less than 40, the color becomes close to black. Therefore, an effect of increasing the depth of the color becomes large when the anti-reflection layer 12 is provided. The lightness L* is more preferably 35 or less, and further preferably 30 or less. The lightness L* is preferably 1 or more, and more preferably 1.5 or more.

The anti-reflection layer 12 is provided in order to give the depth to the color of the glass laminate 10. The anti-reflection layer 12 is the one in which high-refractive index layers 121 and low-refractive index layers 122 are laminated as illustrated in FIG. 2, for example. Here, the high-refractive index layer 121 is a layer having a refractive index of 1.9 or more at a wavelength of 550 nm. Further, the low-refractive index layer 122 is a layer having a refractive index of 1.6 or less at the wavelength of 550 nm.

The anti-reflection layer 12 is preferably provided on a principal surface side which is an outer side when the glass substrate 11 is used as a casing of an electronic device, or the like.

The anti-reflection layer 12 may have a form including one each of the high-refractive index layer 121 and the low-refractive index layer 122 or a configuration including two or more in each of them. In a case of including two or more in each of the high-refractive index layer 121 and the low-refractive index layer 122, a form in which the high-refractive index layers 121 and the low-refractive index layers 122 are laminated alternately is preferable.

From the viewpoint of enhancing anti-reflection performance, it is preferable to increase the number of layers of the high-refractive index layer 121 and the low-refractive index layer 122. On the other hand, from the viewpoint of enhancing productivity, it is preferable to decrease the number of layers of the high-refractive index layer 121 and the low-refractive index layer 122. From compatibility of the anti-reflection performance and the productivity, the total number of layers of the high-refractive index layer 121 and the low-refractive index layer 122 is preferably three to ten, more preferably two to six, and further preferably two to four.

Materials of the high-refractive index layer 121 and the low-refractive index layer 122 can be appropriately selected in consideration of the anti-reflection performance, the productivity, and the like.

As a composing material of the high-refractive index layer 121, there can be cited a niobium oxide (Nb₂O₅), a titanium oxide (TiO₂), a zirconium oxide (ZrO₂), a silicon nitride (SiNₓ), a tantalum oxide (Ta₂O₅), or the like. Only one type of these may be used or two or more types of these may be used. The refractive index of the high-refractive index layer 121 is preferably 1.9 to 2.7.

As a composing material of the low-refractive index layer 122, there can be cited a silicon oxide (SiO₂), a composite oxide of Si and Sn, a composite oxide of Si and Zr, or a composite oxide of Si and Al. Only one type of these may be used or two or more of these may be used. The refractive index of the low-refractive index layer 122 is preferably 1.3 to 1.6.

It is preferable that the high-refractive index layer 121 is constituted of the niobium oxide or the tantalum oxide and the low-refractive index layer 122 is constituted of the silicon oxide from the viewpoint of the productivity, the refractive index, and the like. Further, it is preferable that the high-refractive index layer 121 is constituted of the silicon nitride and the low-refractive index layer 122 is constituted of the composite oxide of Si and Sn, the composite oxide of Si and Zr, or the composite oxide of Si and Al from the viewpoint of hardness, surface roughness, and the like.

A geometrical film thickness of each of the high-refractive index layers 121 is preferably 5 nm or more, and more preferably 10 nm or more. Further, the geometrical film thickness of each of them is preferably 200 nm or less, and more preferably 150 nm or less. Further, a geometrical film thickness of each of the low-refractive index layers 122 is preferably 5 nm or more, and more preferably 10 nm or more. Further, the geometrical film thickness of each of them is preferably 150 nm or less, and more preferably 100 nm or less.

The anti-reflection layer 12 preferably has a surface protection layer 123 on the top layer in order to improve scratch resistance and the like. The surface protection layer 123 is constituted of an oxide containing at least one type of zirconium and titanium and at least one type of boron and silicon, for example. As preferable examples, there can be cited ZrBxOy, ZrSizOy, ZrBxSizOy, and TiSizOy. Among these, in particular, the composite oxides (ZrSizOy, ZrBxSizOy) containing zirconium and silicon are preferable because they are excellent in mechanical strength and, in addition, excellent in chemical stability such as chemical resistance.

Hardness and a refractive index of the surface protection layer 123 can be changed by a content ratio of boron, silicon, and oxygen and a film formation condition. Accordingly, the content ratio of boron, silicon, and oxygen and the film formation condition are preferably selected so as to become desired hardness and refractive index.

A deposition method of the anti-reflection layer 12 is not particularly limited, and various deposition methods can be utilized. As the deposition method, there can be cited pulse sputtering, AC sputtering, digital sputtering, or the like. A dense film can be obtained by the pulse sputtering or the AC sputtering, which is therefore preferable.

The antifouling layer 13 is the one which imparts an antifouling property and further gives the depth to the color, and is provided as necessary. The antifouling layer 13 is constituted of a fluorine-containing organosilicon compound, for example. As the fluorine containing organosilicon compound, the one which imparts the antifouling property, water repellency, or oil repellency can be used.

As the fluorine-containing organosilicon compound, for example, a fluorine-containing organosilicon compound having one or more groups to be selected from a polyfluoropolyether group, a polyfluoroalkylene group, and a polyfluoroalkyl group is preferable. Note that the polyfluoropolyether group means a bivalent group having a structure in which polyfluoroalkylene groups and ether oxygen atoms are bonded alternately.

As a specific example of the fluorine-containing organosilicon compound having one or more groups to be selected from the polyfluoropolyether group, the polyfluoroalkylene group, and the polyfluoroalkyl group, compounds represented by the following general formulas (I) to (V) can be cited.

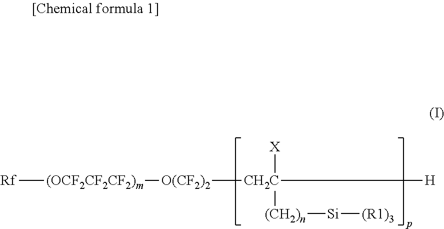

In the formula, Rf is a linear polyfluoroalkyl group having a number of carbon atoms of 1 to 16, X is a hydrogen atom or a low alkyl group having a number of carbon atoms of 1 to 5, R1 is a hydrolyzable group or a halogen atom, m is an integer of 1 to 50, n is an integer of 0 to 2, and p is an integer of 1 to 10.

As an alkyl group in the Rf there can be cited a methyl group, an ethyl group, an n-propyl group, an isopropyl group, an n-butyl group, or the like. As the low alkyl group of the X, there can be cited a methyl group, an ethyl group, an n-propyl group, an isopropyl group, an n-butyl group, or the like. As the hydrolyzable group of the R1, there can be cited an amino group, an alkoxy group, or the like. As the halogen atom of the R1, there can be cited fluorine, chlorine, bromine, iodine, or the like. Preferably, m is an integer of 1 to 30. Preferably, n is an integer of 1 to 2. Preferably, p is an integer of 1 to 8.

C_{q}F_{2q+1}CH₂CH₂Si(NH₂)₃ (II)

In the formula, q is an integer of 1 or more, and preferably 2 to 20.

As a compound represented by the general formula (II), n-trifuloro (1,1,2,2-tetrahydro) propylsilazane (n-CF₃CH₂CH₂Si(NH₂)₃), n-heptafuloro (1,1,2,2-tetrahydro) pentylsilazane (n-C₃F₇CH₂CH₂Si(NH₂)₃), and the like are exemplified.

CF_{q′}F_{2q′+1}CH₂CH₂Si(OCH₃)₃ (III)

In the formula, q′ is an integer of 1 or more, and preferably 1 to 20.

As a compound represented by the general formula (II), 2-(perfluorooctyl) ethyltrimethoxysilane (n-C₈F₁₇CH₂CH₂Si(OCH)₃) and the like are exemplified.

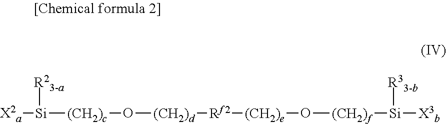

In the formula, R^{f2} is a bivalent linear polyfluoropolyether group represented by —(OC₃F₆)ₛ—(OC₂F₄)ₜ—(OCF₂)ᵤ— (each of s, t, and u is independently an integer of 0 to 300), and each of R² and R³ is independently a monovalent hydrocarbon group having a number of carbon atoms of 1 to 8. X² and X³ are a hydrolyzable group or a halogen atom and may be the same as or different from each other, d and e are an integer independent of each other of 1 to 2, c and fare an integer independent of each other of 1 to 5 (preferably 1 to 2), and a and b are an integer independent of each other of 2 to 3.

As the monovalent hydrocarbon group of the R² and the R³, there can be cited a methyl group, an ethyl group, an n-propyl group, an isopropyl group, an n-butyl group, or the like. As the hydrolyzable group of the X² and the X³, there can be cited an amino group, an alkoxy group, an acyloxy group, an alkenyloxy group, an isocyanate group, or the like. As the halogen atom of the X² and the X³, there can be cited a fluorine atom, a chlorine atom, a bromine atom, an iodine atom, or the like.

s+t+u is preferably 20 to 200, and more preferably 25 to 100 in the Rⁿ which the compound (IV) has. Further, as the R² and the R³, a methyl group, an ethyl group, or a butyl group is more preferable. As the hydrolyzable group indicated by the X² and the X³, an alkoxy group having a number of carbon atoms of 1 to 6 is more preferable, and a methoxy group or an ethoxy group is particularly preferable. Further, each of a and b is preferably 3.

[Chemical formula 3]

F—(CF₂)ᵥ—(OC₃F₈)_{w}—(OC₂F₄)_{y}—(OCF₂)_{z}(CH₂)ₙO(CH₂)ₗ—Si(X⁴)₃₋ₖ(R⁴)ₖ (V)

In the formula, v is an integer of 1 to 3, each of w, y, and z is independently an integer of 0 to 200, h is 1 or 2, i is an integer of 2 to 20, X⁴ is a hydrolyzable group, R⁴ is a linear or branched hydrocarbon group having a number of carbon atoms of 1 to 22, and k is an integer of 0 to 2.

w+y+z is preferably 20 to 300, and more preferably 25 to 100. Further, i is preferably 2 to 10. The X⁴ is preferably an alkoxy group having a number of carbon atoms of 1 to 6, and more preferably a methoxy group or an ethoxy group. As the R⁴, an alkyl group having a number of carbon atoms of 1 to 10 is preferable.

As the fluorine-containing organosilicon compound having one or more groups to be selected from a polyfluoropolyether group, a polyfluoroalkylene group, and a polyfluoroalkyl group, commercial products can be used. As the above ones, for example, KP-801 (brand name, manufactured by Shin-Etsu Chemical Co., Ltd.), KY178 (brand name, manufactured by Shin-Etsu Chemical Co., Ltd.), KY-130 (brand name, manufactured by Shin-Etsu Chemical Co., Ltd.), KY185 (brand name, manufactured by Shin-Etsu Chemical Co., Ltd.), OPTOOL (registered trademark) DSX and OPTOOL (registered trademark) AES (both are a brand name, manufactured by DAIKIN INDUSTRIES, Ltd.) are preferable.

A deposition method of the antifouling layer 13 is not particularly limited, but it is preferable to form a film by vacuum deposition using the above-described material. A geometrical film thickness of the antifouling layer 13 is preferably 1 nm or more from the viewpoint of effectively imparting the antifouling property. Further, the geometrical film thickness of the antifouling layer 13 is preferably 15 nm or less, and more preferably 10 nm or less from the viewpoint of the productivity and the like.

The glass laminate 10 of the present invention preferably has the following optical characteristics. Note that the optical characteristics of the glass laminate 10 are measured in a state where at least the anti-reflection layer 12 is provided on the glass substrate 11. Further, for example, when the glass laminate 10 has the anti-reflection layer 12 and the antifouling layer 13, the measurement is performed in a state where the anti-reflection layer 12 and the antifouling layer 13 are provided.

The minimum of the absorbances in the wavelengths of 380 to 780 nm is preferably 0.01 or more, more preferably 0.2 or more, further preferably 0.7 or more, and particularly preferably 1.0 or more. When the above-described minimum is 0.01 or more, the depth of the color of the glass laminate 10 increases, which is therefore preferable. The larger the above-described minimum becomes, the more the depth of the color of the glass laminate 10 increases, which is therefore preferable.

An average of the absorbances in the wavelengths of 380 to 780 nm is preferably 0.1 or more, more preferably 0.5 or more, further preferably 2.0 or more, and particularly preferably 3.0 or more. When the above-described average is 0.1 or more, the depth of the color of the glass laminate 10 increases in particular, which is therefore preferable. The larger the above-described average becomes, the more the depth of the color of the glass laminate 10 increases, which is therefore preferable.

A minimum of the spectral reflectances for vertically incident light in the wavelengths of 380 to 780 nm regarding a side on which the anti-reflection layer 12 is disposed on the glass substrate 11 is preferably 3% or less. When the above-described minimum is 3% or less, reflection on a surface is suppressed and the depth of the color increases, which is therefore preferable. The lower the above-described minimum is, the more the depth of the color increases, which is therefor preferable. The above-described minimum is preferably 2% or less, and more preferably 1% or less.

An average of the spectral reflectances for the vertically incident light in the wavelengths of 380 to 780 nm regarding the side on which the anti-reflection layer 12 is disposed on the glass substrate 11 is preferably 3% or less. When the above-describe average is 3% or less, reflection of illumination light or the like on a surface is suppressed and the depth of the color increases in particular, which is therefore preferable. The lower the above-described average is, the more the depth of the color increases, which is therefor preferable. The above-described average is preferably 2% or less, and more preferably 1.5% or less. Normally, as long as the above-described average is as low as 0.2%, it is sufficient.

An average of the spectral reflectances for vertically incident light in the wavelengths of 440 to 620 nm is preferably 0.3 to 2%. When the above-described average is 0.3 to 2%, reflection of illumination light or the like on the glass laminate 10 can be suppressed.

A lightness L* of light emitted from an F2 light source in an L*a*b* color system and reflected by the side on which the anti-reflection layer 12 is disposed on the glass substrate 11 is preferably less than 25. The smaller the lightness L* becomes, the closer to black the color becomes, which means that the color has the depth. When the lightness L* is less than 25, the color has sufficient depth, which is therefore preferable. The lightness L* is more preferably 20 or less, further preferably 15 or less, particularly preferably 10 or less, and the most preferably 5 or less. Further, the lightness L* is preferably 1 or more, and more preferably 1.5 or more.

A color shade of reflected light on the glass laminate 10 may be either an achromatic color or a chromatic color. The glass laminate 10 preferably has the following optical characteristics depending on the color shade of the reflected light.

(In a case where a color shade of reflected light is set to an achromatic color) In a case where a color shade of reflected light is set to an achromatic color, the glass laminate 10 preferably has the following optical characteristics.

A difference between a maximum and an average of the spectral reflectances for vertically incident light in the wavelengths of 420 to 680 nm is preferably 0.5% or less, more preferably 0.4% or less, and further preferably 0.3% or less. When the above-described difference becomes 0.5% or less, in a case where reflected light of illumination light or the like is recognized on the glass laminate 10, the reflected light becomes an achromatic color having no specific color tone, which is therefore preferable.

A difference between a maximum and the average of the spectral reflectances for the vertically incident light in the wavelengths of 440 to 620 nm is preferably 0.3% or less, more preferably 0.25% or less, and further preferably 0.2% or less. When the above-described difference becomes 0.3% or less, in a case where reflected light of illumination light or the like is recognized on the glass laminate 10, the reflected light becomes the achromatic color having no specific color tone, which is therefore preferable.

A difference between a maximum and an average of the spectral reflectances for 45° incident light in the wavelengths of 420 to 680 nm is preferably 1.0% or less, more preferably 0.9% or less, and further preferably 0.8% or less. When the above-described difference becomes 1.0% or less, in a case where reflected light of illumination light or the like is recognized on the glass laminate 10, the reflected light becomes the achromatic color having no specific color tone, which is therefore preferable.

A difference between a maximum and an average of the spectral reflectance for 45° incident light in the wavelengths of 440 to 620 nm is preferably 0.6% or less, more preferably 0.55% or less, and further preferably 0.5% or less. When the above-described difference becomes 0.6% or less, in a case where reflected light of illumination light or the like is recognized on the glass laminate 10, the reflected light becomes the achromatic color having no specific color tone, which is therefore preferable.

(In a case where a color shade of reflected light is set to a chromatic color) In a case where a color shade of reflected light is set to a chromatic color, the glass laminate 10 preferably has the following optical characteristics.

The difference between the maximum and the average of the spectral reflectance for the vertically incident light in the wavelengths of 420 to 680 nm is preferably more than 0.5%, more preferably more than 0.6%, and further preferably more than 0.7%. When the above-described difference becomes more than 0.5%, in a case where reflected light of illumination light or the like is recognized on the glass laminate 10, the reflected light has a specific color tone, and therefore a color scheme to a peripheral member of the glass laminate 10 can be adjusted.

The difference between the maximum and the average of the spectral reflectances for the vertically incident light in the wavelengths of 440 to 620 nm is preferably more than 0.3%, more preferably more than 0.4%, and further preferably more than 0.5%. When the above-described difference becomes more than 0.3%, in a case where reflected light of illumination light or the like is recognized on the glass laminate 10, the reflected light has a specific color tone, and therefore a color scheme to the peripheral member of the glass laminate 10 can be adjusted.

The difference between the maximum and the average of the spectral reflectances for the 45° incident light in the wavelengths of 420 to 680 nm is preferably more than 1.0%, more preferably more than 1.1%, and further preferably more than 1.2%. When the above-described difference becomes more than 1.0%, in a case where reflected light of illumination light or the like is recognized on the glass laminate 10, the reflected light has a specific color tone, and therefore a color scheme to the peripheral member of the glass laminate 10 can be adjusted.

The difference between the maximum and the average of the spectral reflectances for the 45° incident light in the wavelengths of 440 to 620 nm is preferably more than 0.6%, more preferably more than 0.7%, and further preferably more than 0.8%. When the above-described difference becomes more than 0.6%, in a case where reflected light of illumination light or the like is recognized on the glass laminate 10, the reflected light has a specific color tone, and therefore a color scheme to the peripheral member of the glass laminate 10 can be adjusted.

The glass laminate 10 can be suitably used for an exterior of portable electronic devices. The portable electronic device has a concept of including a communication device and an information device which are carried to be used. For example, as the communication device, there can be cited a communication terminal, a broadcast receiver, and the like.

As the communication terminal, there can be cited a mobile phone, PHS (Personal Handy-phone System), a smartphone, PDA (Personal Data Assistance), PND (Portable Navigation Device, portable car navigation system), and the like. As the broadcast receiver, there can be cited a portable radio, a portable television set, a one-seg receiver, and the like.

Further, for example, as the information device, there can be cited a digital camera, a video camera, a portable music player, a sound recorder, a portable DVD player, a potable game machine, a laptop personal computer, a tablet PC, an electronic dictionary, an electronic notebook, an electronic book reader, a portable printer, a portable scanner, and the like.

Further, the glass laminate 10 can also be utilized for a stationary electronic device or an electronic device which is installed in an automobile. Using the glass laminate 10 for an exterior of these portable and stationary electronic devices allows design thereof to be excellent. Moreover, the glass laminate 10 can also be utilized for an exterior of products other than the electronic devices. The products other than the electronic devices are building materials or indoor devices, such as furniture and various household appliances, and are not particularly limited.

When the glass laminate 10 is applied to the exterior of the electronic device and the like, a casing may be constituted using only the glass laminate 10 or the glass laminate 10 may be laminated on an outer surface of a casing constituted of other materials, for example.

### EXAMPLES

Hereinafter, the present invention will be described more specifically referring to examples.

Note that the present invention is not limited to these examples.

### Example 1 to Example 11

Glass substrates A to D each having glass composition, absorbance, reflectance, and chromaticity as illustrated in Table 1 were prepared. Note that measurement of the absorbance, the reflectance, and the chromaticity was performed based on the later-described measuring method. Then, test pieces each having a configuration as illustrated in Table 2 were produced using these glass substrates.

Here, the test pieces in Example 1, Example 3, and Example 6 were each produced by forming only an anti-reflection layer on one principal surface of each of the glass substrates. The test pieces in Example 2, Example 4, Example 5, and Example 7 were each produced by forming the anti-reflection layer and an antifouling layer in order on one principal surface of each of the glass substrates. The glass substrates were used as they were as the test pieces without forming either of the anti-reflection layer and the antifouling layer in Example 8 to Example 11. Example 1 to Example 7 are the examples of the present invention, and Example 8 to Example 11 are comparative examples of the present invention.

Note that the anti-reflection layer was formed by depositing a first high-refractive index layer, a first low-refractive index layer, a second high-refractive index layer, and a second low-refractive index layer in order as indicated below.

First, pulse sputtering was performed using a niobium oxide target while introducing mixed gas in which oxygen gas of 10 vol % was mixed with argon gas. Thereby, the first high-refractive index layer having a geometrical thickness of 14 nm and constituted of a niobium oxide (niobia) was formed on the glass substrate. Note that a brand name “NBO target” manufactured by AGC Ceramics Co., Ltd. was used for the niobium oxide target. Further, the pulse sputtering was performed under a condition of a pressure of 0.3 Pa, a frequency of 20 kHz, a power density of 3.8 W/cm², and a reverse pulse width of 5 μsec.

Next, the pulse sputtering was performed using a silicon target while introducing mixed gas in which oxygen gas of 40 vol % was mixed with argon gas. Thereby, the first low-refractive index layer having a geometrical thickness of 35 nm and constituted of a silicon oxide (silica) was formed on the first high-refractive index layer. Note that the pulse sputtering was performed under the condition of the pressure of 0.3 Pa, the frequency of 20 kHz, the power density of 3.8 W/cm², and the reverse pulse width of 5 μsec.

Next, the pulse sputtering was performed using the niobium oxide target while introducing the mixed gas in which oxygen gas of 10 vol % was mixed with argon gas. Thereby, the second high-refractive index layer having a geometrical thickness of 118 nm and constituted of the niobium oxide (niobia) was formed on the first low-refractive index layer. Note that the brand name “NBO target” manufactured by AGC Ceramics Co., Ltd. was used for the niobium oxide target. Further, the pulse sputtering was performed under the condition of the pressure of 0.3 Pa, the frequency of 20 kHz, the power density of 3.8 W/cm², and the reverse pulse width of 5 μsec.

Next, the pulse sputtering was performed using the silicon target while introducing the mixed gas in which oxygen gas of 40 vol % was mixed with argon gas. Thereby, the second low-refractive index layer having a geometrical thickness of 84 nm and constituted of the silicon oxide (silica) was formed on the second high-refractive index layer. Note that the pulse sputtering was performed under the condition of the pressure of 0.3 Pa, the frequency of 20 kHz, the power density of 3.8 W/cm², and the reverse pulse width of 5 μsec.

Further, an antifouling layer was formed by forming a film as follows.

First, a brand name “OPTOOL (registered trademark) DSX agent” manufactured by DAIKIN INDUSTRIES, Ltd. which was a material was introduced in a heating container. Thereafter, the interior of the heating container was deaerated by a vacuum pump for ten or more hours, and a solvent in a solution was removed to be prepared as a composition for forming an antifouling layer. The heating container containing this composition was heated to 270° C. and thereafter kept for ten minutes until a temperature stabilized.

Separately, the glass substrate on which the anti-reflection layer was formed was disposed in a vacuum chamber, and the composition was supplied from the heating container through a nozzle connected to this vacuum chamber. At this time, a geometrical thickness was measured by a quartz resonator monitor installed in the vacuum chamber, and the composition was supplied until the geometrical thickness became 7 nm. Thereafter, the glass substrate was taken from the vacuum chamber, its film formation surface was turned upward, the glass substrate was placed on a hot plate, and heat treatment was performed at 150° C. for 60 minutes in the atmosphere. Thereby, the antifouling layer was formed on the anti-reflection layer.

Next, regarding each of the test pieces, optical characteristics were evaluated as follows.

Note that the optical characteristics of the glass substrates were also similarly evaluated.

(Absorbance)

Spectral transmittance for vertically incident light on each of the test pieces was measured using an ultraviolet-visible-near-infrared spectrophotometer V-570 manufactured by JASCO Corporation. Note that in the measurement of the spectral reflectance, measurement light was incident from a principal surface side on which the anti-reflection layer was formed with respect to the glass substrate. Thereafter, absorbance (A) was calculated from spectral reflectance (T) by the following formula (1) to find a minimum and an average of the absorbances in the wavelengths of 380 to 780 nm.

A=−log₁₀(T) (1)

(Reflectance)

The spectral transmittance for vertically incident light on each of the test pieces was measured by the ultraviolet-visible-near-infrared spectrophotometer V-570 manufactured by JASCO Corporation. Note that in the measurement of the spectral reflectance, measurement light was incident from the principal surface side on which the anti-reflection layer was formed with respect to the glass substrate. Then, a minimum and an average of the reflectances in the wavelengths of 380 to 780 nm were found from this spectral transmittance.

(Chromaticity)

Chromaticity of reflected light in an L*a*b* color system standardized by CIE was measured. An F2 light source was used as a light source, and the chromaticity measurement of reflected light on the principal surface side on which the anti-reflection layer was formed with respect to the glass substrate was performed. A spectro-colorimeter (manufactured by X-Rite Inc., Colori 7) was used for the chromaticity measurement. Note that a white resin plate was put on a rear surface side (a rear surface of a surface which was irradiated with light from the light source) of the glass to perform the measurement.

TABLE 1

| | | Glass substrate | | | |
|---|---|---|---|---|---|
| | | A | B | C | D |
| Composition | SiO₂ | 69.3 | 62.0 | 63.1 | 71.2 |
| [mol %] | Al₂O₃ | 5.8 | 7.7 | 7.9 | 3.1 |
| | Na₂O | 11.6 | 12.1 | 12.3 | 16.6 |
| | K₂O | 0 | 3.9 | 3.9 | 0.2 |
| | Li₂O | 0 | 0 | 0 | 0 |
| | MgO | 9.6 | 10.1 | 10.3 | 8.5 |
| | ZrO₂ | 0 | 0.5 | 0.42 | 0 |
| | Co₃O₄ | 0.4 | 0.4 | 0.05 | 0.002 |
| | Fe₂O₃ | 3.3 | 3.3 | 0 | 0 |
| | TiO₂ | 0 | 0 | 0.25 | 0 |
| | CuO | 0 | 0 | 0.98 | 0.13 |
| | NiO | 0 | 0 | 0.7 | 0.14 |
| | SO₃ | 0.1 | 0.1 | 0.1 | 0.1 |
| Absorbance | minimum | 1.35 | 0.88 | 0.27 | 0.01 |
| | average | 3.34 | 3.07 | 0.90 | 0.19 |
| Reflectance [%] | minimum | 4.53 | 4.65 | 4.20 | 3.94 |
| | average | 4.60 | 4.77 | 4.32 | 4.09 |
| Chromaticity | L* | 25.26 | 25.39 | 26.09 | 60.79 |
| L*a*b* color system | a* | 0.08 | −0.02 | −0.48 | 0.35 |
| (F2 light source) | b* | −0.70 | −0.97 | −1.86 | 0.54 |

TABLE 2

| | | Example | | | | | | | | | | |
|---|---|---|---|---|---|---|---|---|---|---|---|---|
| | | 1 | 2 | 3 | 4 | 5 | 6 | 7 | 8 | 9 | 10 | 11 |
| Type of glass | | A | A | B | B | C | D | D | A | B | C | D |
| Sheet thickness [mm] | | 1.1 | 1.1 | 0.8 | 0.8 | 0.8 | 1.2 | 1.2 | 1.1 | 0.8 | 0.8 | 1.2 |
| Anti-reflection layer | | presence | presence | presence | presence | presence | presence | presence | absence | absence | absence | absence |
| Antifouling layer | | absence | presence | absence | presence | presence | absence | presence | absence | absence | absence | absence |
| Absorbance | minimum | 1.26 | 1.24 | 0.84 | 0.82 | 0.27 | 0.02 | 0.02 | 1.35 | 0.88 | 0.27 | 0.01 |
| | average | >3.34 | >3.34 | >3.07 | >3.07 | 0.86 | 0.18 | 0.18 | 3.34 | 3.07 | 0.90 | 0.19 |
| Reflectance | minimum | 0.06 | 0.06 | 0.06 | 0.06 | 0.10 | 0.08 | 0.07 | 4.53 | 4.65 | 4.20 | 3.94 |
| [%] | average | 1.02 | 1.00 | 1.08 | 1.02 | 1.23 | 1.04 | 0.96 | 4.60 | 4.77 | 4.32 | 4.09 |
| Chromaticity | L* | 2.74 | 2.09 | 2.42 | 1.83 | 7.53 | 58.79 | 58.55 | 25.26 | 25.39 | 26.09 | 60.79 |
| L*a*b* color | a* | −1.14 | −1.08 | −0.5 | −1.07 | −1.74 | 0.51 | 0.49 | 0.08 | −0.02 | −0.48 | 0.35 |
| system | b* | 2.49 | 0.82 | 1.5 | 0.42 | −4.87 | 1.01 | 1.09 | −0.70 | −0.97 | −1.86 | 0.54 |
| (F2 light | | | | | | | | | | | | |
| source) | | | | | | | | | | | | |

As obviously seen from Table 2, when the same glass substrate is used, it is found that L* is decreased and depth appears in color by providing the anti-reflection layer. In particular, it is found that, L* is low as indicated by the glass substrates A and B, so that the closer to black the color becomes, the more greatly L* is decreased and the more depth appears in the color by providing the anti-reflection layer.

Note that regarding results of average of the absorbance in Table 2, an indication of a minimum of more than 0% in transmittance is 0.01% in the measuring device for the used spectral transmittance, and this becomes 4.0 when converted to the absorbance. Therefore, Example 1 to Example 4 including data of 4.0 in the absorbances were each considered to be over the average of the obtained absorbances.

### Example 21 to Example 28

Test pieces in Example 21 to Example 28 were produced as indicated below. Note that any of Example 21 to Example 28 is the example of the present invention.

### Example 21

On a surface of the glass substrate A (sheet thickness 1.0 mm) presented in Table 1, the test piece was produced by depositing high-refractive index layers constituted of a niobium oxide and low-refractive index layers constituted of a silicon oxide alternately as an anti-reflection layer as presented in Table 3. Note that layer numbers in the table indicated a layer on a glass substrate side as a first layer. Further, the deposition of the high-refractive index layers constituted of the niobium oxide was performed by AC sputtering using a niobium target while introducing mixed gas of argon gas and oxygen gas. The deposition of the low-refractive index layers constituted of the silicon oxide was performed by the AC sputtering using a silicon target while introducing the mixed gas of the argon gas and the oxygen gas. Further, an antifouling layer was not formed.

TABLE 3
Example 21

| Layer number | Film material | Physical film thickness (nm) |
|---|---|---|
| 1 | Nb₂O₅ | 10.41 |
| 2 | SiO₂ | 53.06 |
| 3 | Nb₂O₅ | 32.70 |
| 4 | SiO₂ | 38.73 |
| 5 | Nb₂O₅ | 28.91 |
| 6 | SiO₂ | 97.56 |

### Example 22

The test piece was produced similarly to Example 21 except that a thickness of an anti-reflection layer was changed as presented in Table 4.

TABLE 4
Example 22

| Layer number | Film material | Physical film thickness (nm) |
|---|---|---|
| 1 | Nb₂O₅ | 11.81 |
| 2 | SiO₂ | 45.30 |
| 3 | Nb₂O₅ | 47.05 |
| 4 | SiO₂ | 18.85 |
| 5 | Nb₂O₅ | 43.83 |
| 6 | SiO₂ | 93.91 |

### Example 23

The test piece was produced similarly to Example 21 except that a thickness of an anti-reflection layer was changed as presented in Table 5.

TABLE 5
Example 23

| Layer number | Film material | Physical film thickness (nm) |
|---|---|---|
| 1 | Nb₂O₅ | 12.05 |
| 2 | SiO₂ | 44.39 |
| 3 | Nb₂O₅ | 50.34 |
| 4 | SiO₂ | 18.47 |
| 5 | Nb₂O₅ | 42.08 |
| 6 | SiO₂ | 92.03 |

### Example 24

The test piece was produced similarly to Example 21 except that a thickness of an anti-reflection layer was changed as presented in Table 6.

TABLE 6
Example 24

| Layer number | Film material | Physical film thickness (nm) |
|---|---|---|
| 1 | Nb₂O₅ | 11.58 |
| 2 | SiO₂ | 38.29 |
| 3 | Nb₂O₅ | 51.04 |
| 4 | SiO₂ | 17.09 |
| 5 | Nb₂O₅ | 39.58 |
| 6 | SiO₂ | 92.38 |

### Example 25

The test piece was produced similarly to Example 21 except that a thickness of an anti-reflection layer was changed as presented in Table 7.

TABLE 7
Example 25

| Layer number | Film material | Physical film thickness (nm) |
|---|---|---|
| 1 | Nb₂O₅ | 10.83 |
| 2 | SiO₂ | 59.08 |
| 3 | Nb₂O₅ | 32.23 |
| 4 | SiO₂ | 43.12 |
| 5 | Nb₂O₅ | 25.72 |
| 6 | SiO₂ | 108.63 |

### Example 26

The test piece was produced similarly to Example 21 except that a thickness of an anti-reflection layer was changed as presented in Table 8.

TABLE 8
Example 26

| Layer number | Film material | Physical film thickness (nm) |
|---|---|---|
| 1 | Nb₂O₅ | 11.45 |
| 2 | SiO₂ | 74.85 |
| 3 | Nb₂O₅ | 33.68 |
| 4 | SiO₂ | 54.64 |
| 5 | Nb₂O₅ | 30.64 |
| 6 | SiO₂ | 137.63 |

### Example 27

The test piece was produced similarly to Example 21 except that a thickness of an anti-reflection layer was changed as presented in Table 9.

TABLE 9
Example 27

| Layer number | Film material | Physical film thickness (nm) |
|---|---|---|
| 1 | Nb₂O₅ | 11.45 |
| 2 | SiO₂ | 52.53 |
| 3 | Nb₂O₅ | 33.68 |
| 4 | SiO₂ | 38.34 |
| 5 | Nb₂O₅ | 30.64 |
| 6 | SiO₂ | 96.58 |

### Example 28

The test piece was produced similarly to Example 21 except that a thickness of an anti-reflection layer was changed as presented in Table 10.

TABLE 10
Example 28

| Layer number | Film material | Physical film thickness (nm) |
|---|---|---|
| 1 | Nb₂O₅ | 11.04 |
| 2 | SiO₂ | 53.83 |
| 3 | Nb₂O₅ | 24.36 |
| 4 | SiO₂ | 41.08 |
| 5 | Nb₂O₅ | 33.44 |
| 6 | SiO₂ | 78.29 |

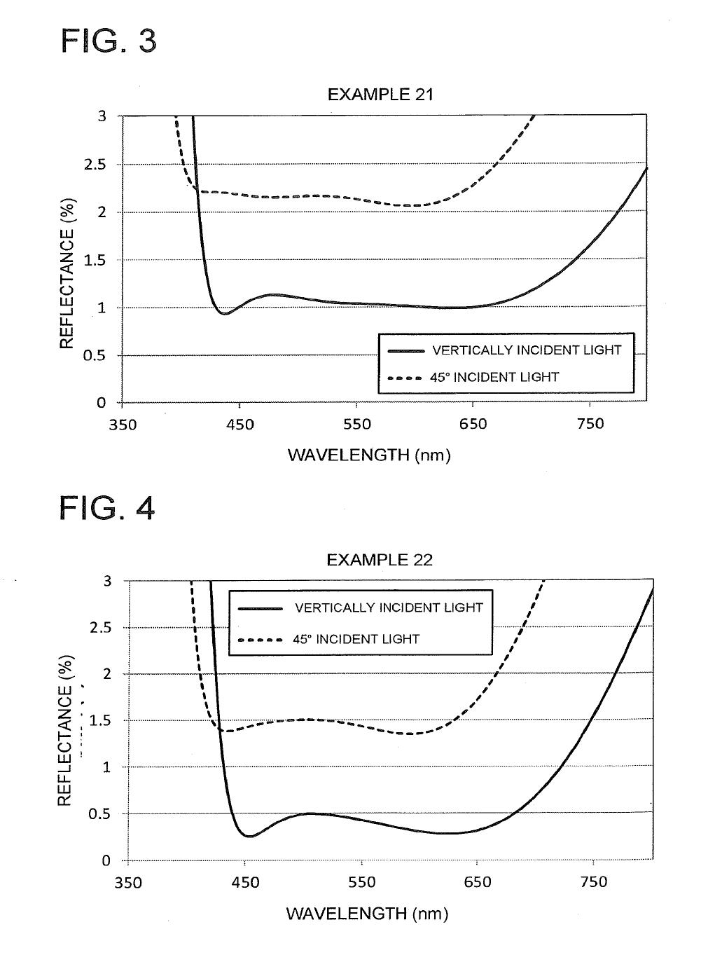

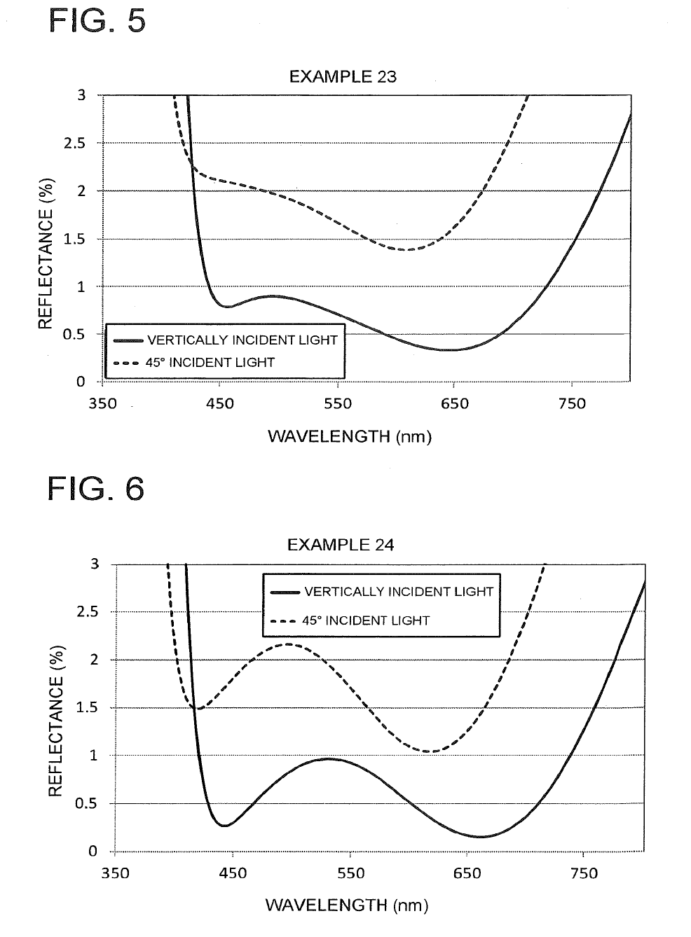

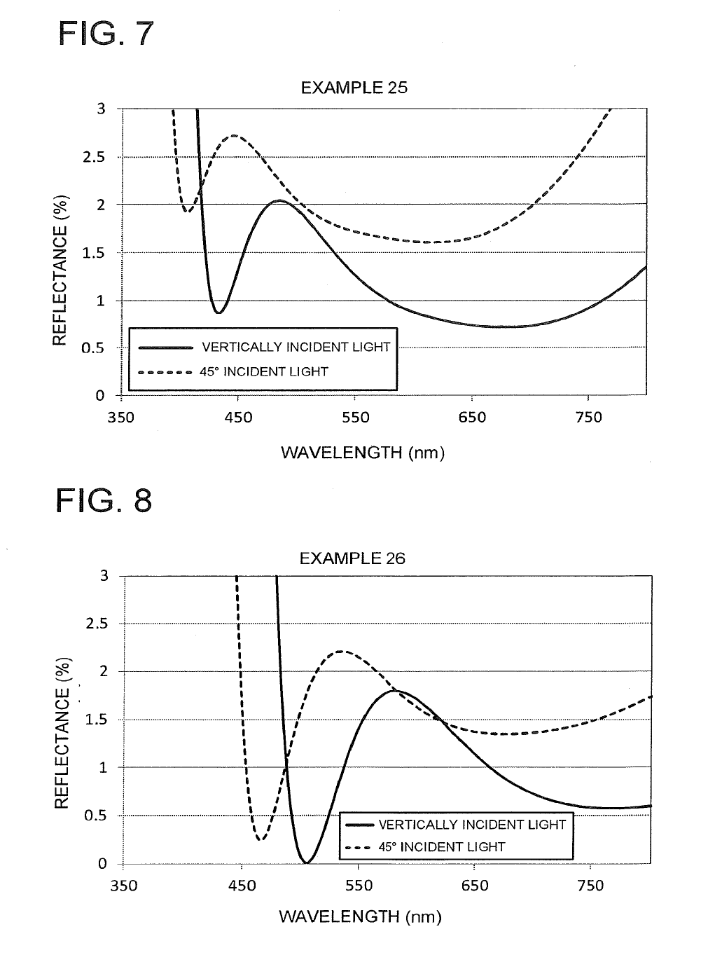

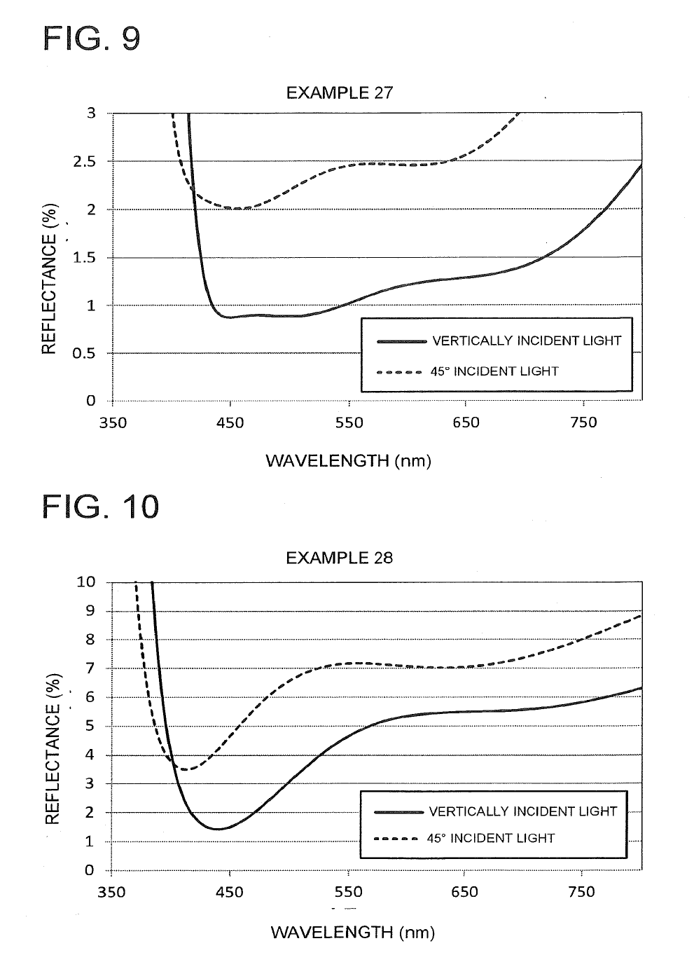

Next, regarding the test pieces in Example 21 to Example 28, optical characteristics were evaluated as follows. Table 11 presents results. Further, FIG. 3 to FIG. 10 illustrate measurement results of spectral reflectance of the test pieces in Example 21 to Example 28.

(Absorbance)

Absorbance (minimum and average) in Example 21 to Example 28 was substantially the same (a minimum of 1.35, an average of 3.34) as the absorbance of the glass substrate A.

(Reflectance)

Spectral transmittance for vertically incident light was measured regarding each of the test pieces to find a maximum and an average of the reflectances in the wavelengths of 440 to 620 nm and a difference between these values, a maximum and an average of the reflectances in the wavelengths of 420 to 680 nm and a difference between these values, and a minimum and an average of the reflectance in the wavelengths of 380 to 780 nm. Further, spectral transmittance for 45° incident light was measured regarding each of the test pieces to find a maximum and an average of the reflectances in the wavelengths of 440 to 620 nm and a difference between these values, a maximum and an average of the reflectances in the wavelengths of 420 to 680 nm and a difference between these values. Note that the ultraviolet-visible-near-infrared spectrophotometer V-570 manufactured by JASCO Corporation was used for the measurement of the spectral reflectance.

(Chromaticity, Color Shade)

Chromaticity of reflected light was measured similarly to Example 1 to Example 11. Note that the measurement was performed regarding vertically incident light and 450 incident light. Further, color shades of the reflected light were found by the above chromaticity. Note that in the table, the chromaticity indicated only chromaticity of the vertically incident light.

TABLE 11

| | Wavelength | Incident | | Example | | | | | | | |
|---|---|---|---|---|---|---|---|---|---|---|---|
| | [nm] | direction | Evaluation | 21 | 22 | 23 | 24 | 25 | 26 | 27 | 28 |
| Reflectance | 440~620 | Vertical | AVG | 1.092 | 0.389 | 0.721 | 0.685 | 1.398 | 4.189 | 1.010 | 3.777 |
| [%] | | | MAX | 1.187 | 0.532 | 1.025 | 0.967 | 2.045 | 29.594 | 1.254 | 5.437 |
| | | | MAX − AVG | 0.095 | 0.143 | 0.304 | 0.282 | 0.647 | 25.405 | 0.244 | 1.660 |
| | | 45° | AVG | 1.933 | 1.256 | 1.765 | 1.704 | 1.975 | 1.706 | 2.299 | 6.508 |
| | | | MAX | 2.045 | 1.397 | 2.144 | 2.163 | 2.719 | 4.918 | 2.473 | 7.179 |
| | | | MAX − AVG | 0.112 | 0.141 | 0.379 | 0.459 | 0.744 | 3.212 | 0.174 | 0.671 |
| | 420~680 | Vertical | AVG | 1.087 | 0.431 | 0.750 | 0.572 | 1.231 | 6.438 | 1.104 | 4.002 |
| | | | MAX | 1.278 | 2.181 | 3.378 | 1.117 | 2.045 | 51.273 | 1.975 | 5.523 |
| | | | MAX − AVG | 0.191 | 1.750 | 2.628 | 0.545 | 0.814 | 44.835 | 0.871 | 1.521 |
| | | 45° | AVG | 1.959 | 1.305 | 1.793 | 1.616 | 1.946 | 2.531 | 2.354 | 6.430 |
| | | | MAX | 2.289 | 2.041 | 2.417 | 2.163 | 2.719 | 20.345 | 2.818 | 7.200 |
| | | | MAX − AVG | 0.330 | 0.736 | 0.624 | 0.547 | 0.773 | 17.814 | 0.464 | 0.770 |
| | 380~780 | Vertical | MIN | 0.940 | 0.257 | 0.332 | 0.155 | 0.718 | 0.008 | 0.875 | 1.429 |
| | | | AVG | 1.817 | 1.760 | 2.452 | 1.533 | 2.611 | 11.257 | 2.407 | 4.604 |

| Chromaticity | | L* | 11.37 | 4.76 | 5.96 | 6.87 | 10.99 | 13.41 | 9.48 | 25.35 |
|---|---|---|---|---|---|---|---|---|---|---|
| L*a*b* color system | | a* | −0.57 | 0.33 | 0.50 | −7.93 | −6.15 | 72.34 | 3.04 | −0.31 |
| (F2 light source) | | b* | 1.58 | −4.97 | −8.04 | 3.37 | −3.84 | −68.08 | 0.26 | 19.12 |
| Color shade | Vertical | | WT | WT | BL | GN | LB | RV | LR | YL |
| | 45° | | WT | WT | BL | BG | LV | LV | BE | LG |

Note that in the table, “MIN” presents a minimum, “MAX” presents a maximum, and “AVG” presents an average. Further, “WT” presents an achromatic color, “BL” presents blue, “GN” presents green, “BG” presents blue-green, “LB” presents light blue, “LV” presents light violet, “RV” presents red-violet, “LR” presents light red, “BE” presents beige, “YL” presents yellow, and “LG” presents light green.

As obviously seen from Table 11, adjusting the reflectance makes it possible to adjust the color shade of reflected light to an achromatic color or a chromatic color. Further, in a case of the chromatic color, it is possible to adjust a specific color shade.

What is claimed is:

1. A glass laminate comprising: a glass substrate; and an anti-reflection layer laminated on the glass substrate, wherein
a minimum of absorbances of the glass laminate in wavelengths of 380 to 780 nm is 0.01 or more.

2. The glass laminate according to claim 1, wherein an average of the absorbances of the glass laminate in the wavelengths of 380 to 780 nm is 0.1 or more.

3. The glass laminate according to claim 1, wherein a difference between a maximum and an average of spectral reflectances of the glass laminate for vertically incident light in wavelengths of 420 to 680 nm is 0.5% or less.

4. The glass laminate according to claim 3, wherein a difference between a maximum and an average of spectral reflectances of the glass laminate for vertically incident light in wavelengths of 440 to 620 nm is 0.3% or less.

5. The glass laminate according to claim 1, wherein a difference between a maximum and an average of spectral reflectances of the glass laminate for 45° incident light in wavelengths of 420 to 680 nm is 1.0% or less.

6. The glass laminate according to claim 5, wherein a difference between a maximum and an average of spectral reflectances of the glass laminate for 45° incident light in wavelengths of 440 to 620 nm is 0.6% or less.

7. The glass laminate according to claim 1, wherein a difference between a maximum and an average of spectral reflectances of the glass laminate for vertically incident light in wavelengths of 420 to 680 nm is more than 0.5%.

8. The glass laminate according to claim 7, wherein a difference between a maximum and an average of spectral reflectances of the glass laminate for vertically incident light in wavelengths of 440 to 620 nm is more than 0.3%.

9. The glass laminate according to claim 1, wherein a difference between a maximum and an average of spectral reflectances of the glass laminate for 45° incident light in wavelengths of 420 to 680 nm is more than 1.0%.

10. The glass laminate according to claim 9, wherein a difference between a maximum and an average of spectral reflectances of the glass laminate for 45° incident light in wavelengths of 440 to 620 nm is more than 0.6%.

11. The glass laminate according to claim 1, wherein a minimum of spectral reflectances of an anti-reflection layer side of the glass laminate for vertically incident light in wavelengths of 380 to 780 nm is 3% or less.

12. The glass laminate according to claim 1, wherein an average of spectral reflectances of an anti-reflection layer side of the glass laminate for vertically incident light in wavelengths of 380 to 780 nm is 3% or less.

13. The glass laminate according to claim 12, wherein the average of the spectral reflectances is 0.2 to 3%.

14. The glass laminate according to claim 1, wherein a lightness L* of light emitted from an F2 light source in an L*a*b* color system and reflected by an anti-reflection layer side of the glass laminate is less than 25.

15. The glass laminate according to claim 14, wherein the lightness L* is 1.5 to 20.

16. The glass laminate according to claim 1, further comprising an antifouling layer on the anti-reflection layer.

17. The glass laminate according to claim 1, wherein the anti-reflection layer comprises: a multi-layer and a surface protection layer on the multi-layer, the multi-layer including a high-refractive index layer and a low-refractive index layer.

18. The glass laminate according to claim 1, wherein the anti-reflection layer comprises three to ten layers.

19. The glass laminate according to claim 1, wherein an average spectral reflectance of the glass laminate for the vertically incident light in wavelengths of 440 to 620 nm is 0.3 to 2%.

20. The glass laminate according to claim 1, wherein a surface roughness Ra of an anti-reflection layer side of the glass substrate according to JIS B0633 (2001) is 0.2 to 1 μm.

21. The glass laminate according to claim 1, for an exterior of an electronic device.

22. The glass laminate according to claim 21, wherein the electronic device is a portable electronic device.

23. The glass laminate according to claim 1, for an exterior of a building material or an indoor device.

24. A portable electronic device comprising an electric device and the glass laminate according to claim 1 on the electronic device.
